(19) United States
(12) Patent Application Publication
(10) Pub. No.: US 2014/0097871 A1
(43) Pub. Date: Apr. 10, 2014

(54) Latch comparator device and operation method thereof

(71) Applicant: NOVATEK MICROELECTRONICS CORP., Hsin-Chu (TW)

(72) Inventor: Jer-Hao Hsu, Hsinchu County (TW)

(73) Assignee: NOVATEK Microelectronics Corp., Hsin-Chu (TW)

(21) Appl. No.: 13/736,967

(22) Filed: Jan. 9, 2013

(30) Foreign Application Priority Data
Oct. 4, 2012 (TW) 101136656

(51) Int. Cl. G01R 19/10

(52) U.S. Cl. CPC G01R 19/10
USPC 327/52

(57) ABSTRACT

A latch comparator device includes a differential input amplifier coupled between a first system voltage and a second system voltage and including a first differential output signal terminal and a second differential output signal terminal, a latch coupled to a third system voltage including a first latch signal terminal and a second latch signal terminal, a switch module including a first switch device and a second switch device, wherein the first switch device is coupled between the first differential output signal terminal and the second latch signal terminal and the second switch device is coupled between the second differential output signal terminal and the first latch signal terminal, and a third switch device is coupled between the latch and a fourth system voltage.

### BACKGROUND OF THE INVENTION

1. Field of the Invention

The present invention relates to a latch comparator device and an operational method thereof, and more particularly, to a latch comparator device and an operational method thereof to process an analog-to-digital signal conversion via utilizing conduction conditions of a plurality of switch devices.

2. Description of the Prior Art

For advanced wireless communication systems and touch display devices, all digital electronic suppliers have continuously developed various software and firmware to comply with users' requirements. Also, they have focused on how to increase convenience of hardware to correspondingly improve processing efficiency of the hardware, wherein a latch comparator device is utilized to process the analog-to-digital conversion technique and becomes one of the most important components.

Please refer to FIG. 1, which is a schematic diagram of a conventional latch comparator device 10. As shown in FIG. 1, the latch comparator device 10 comprises a differential input amplifier 100 and a latch 102. The differential input amplifier 100 comprises transistors T1-T4 and a current source CS, and the latch comprises transistors T5-T12. In detail, the differential input amplifier 100 utilizes gates of the transistors T1, T2 to receive input signals IP, IN, and accordingly, a difference between the input signals IP, IN is operated on for outputting a differential output signal via a pre-amplification operation. Between the differential input amplifier 100 and the latch 102, gates of the transistors T3, T6 and gates of the transistors T4, T5 are coupled to each other, such that gates of transistors T5, T6 of the latch 102 are utilized to receive the differential output signal of the pre-amplification operation. Under such circumstances, the transistor T12 of the latch 102 receives a control signal S_Latch to correspondingly control a conduction condition of the transistor T12, so as to sequentially conduct the transistors T9, T10 (contrarily, the transistors T7, T8 are conducted all the time). The latch 102 outputs a latch signal via a latch operation at output terminals OP1, OP2, and the latch signal is utilized for the following digital signal processing. However, the latch comparator device 10 only utilizes the control signal S_Latch to adaptively conduct the transistors T9, T10, and the transistors T7, T8 are conducted all the time, which lacks of an isolation mechanism between the gates of the transistors T1, T2 (i.e. the input terminals) and the output terminals OP1, OP2 to effectively isolate a signal interference between the input terminals and the output terminals. Accordingly, the kick back noise effect is easily generated, and the latch comparator device 10 provides a lower processing efficiency.

### SUMMARY OF THE INVENTION

A latch comparator device and an operational method thereof are provided to process an analog-to-digital signal conversion via utilizing conduction conditions of a plurality of switch devices. The latch comparator device and the operational method thereof can effectively avoid generation of the kick back noise effect to correspondingly improve signal conversion accuracy as well as processing efficiency.

According to an aspect of the disclosure, a latch comparator device for processing an analog-to-digital signal transformation is provided. The latch comparator device includes a differential input amplifier coupled between a first system voltage and a second system voltage and comprising a first differential output signal terminal and a second differential output signal terminal, a latch coupled to a third system voltage comprising a first latch signal terminal and a second latch signal terminal, a switch module comprising a first switch device and a second switch device, wherein the first switch device is coupled between the first differential output signal terminal and the second latch signal terminal and the second switch device is coupled between the second differential output signal terminal and the first latch signal terminal, and a third switch device is coupled between the latch and a fourth system voltage.

According to an aspect of the disclosure, a latch comparator device for processing an analog-to-digital signal transformation is provided. The latch comparator device includes a differential input amplifier including a differential input module, coupled to a first differential output signal terminal and a second differential output signal terminal, a load module, coupled between the first differential output signal terminal, the second differential output signal terminal and a first system voltage, and a current source, coupled between the differential input module and a second system voltage, and a latch including a first latch transistor comprising a first terminal, a second terminal and a third terminal, wherein the second terminal is coupled to a first latch signal terminal, the first terminal is coupled to a second latch signal terminal and the third terminal is coupled to a third switch device, a second latch transistor comprising a first terminal, a second terminal and a third terminal, wherein the first terminal is coupled to the first latch signal terminal, the second terminal is coupled to the second latch signal terminal and the third terminal is coupled to the third switch device, a third latch transistor comprising a first terminal, a second terminal and a third terminal, wherein the first terminal is coupled to the second latch signal terminal, the second terminal is coupled to the first latch signal terminal and the third terminal is coupled to the first system voltage, and a fourth latch transistor comprising a first terminal, a second terminal and a third terminal, wherein the first terminal is coupled to the first latch signal terminal, the second terminal is coupled to the second latch signal terminal and the third terminal is coupled to the first system voltage, and a switch module comprising a first switch device and a second switch device, wherein the first switch device is coupled between the first differential output signal terminal and the second latch signal terminal and the second switch device is coupled between the second differential output signal terminal and the first latch signal terminal, and a third switch device, coupled between the latch and the second system voltage.

According to an aspect of the disclosure, an operational method for a latch comparator device is provided. The operational method includes processing a pre-amplification operation, wherein the pre-amplification operation includes disconnecting the latch and a system power, connecting the differential input amplifier and the latch, utilizing the differential input amplifier to receive and amplify a first differential input signal and a second differential input signal, so as to generate a first differential output signal and a second differential output signal, and utilizing the latch to sample voltage levels of the first differential output signal and the second differential output signal, so as to generate a first initial voltage level of a first latch output signal and a second initial voltage level of a second latch output signal, and processing a latch operation after the pre-amplification operation, wherein the latch operation includes disconnecting the differential input amplifier and the latch, connecting a side of the latch to the system voltage, and utilizing the latch to regenerate voltage levels of the first latch output signal and the second latch output signal according to the first initial voltage level and the second initial voltage level, to reach a digital signal voltage level.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a conventional latch comparator device.

FIG. 2 illustrates a schematic diagram of a latch comparator device according to an embodiment of the invention.

FIG. 3 illustrates a schematic diagram of related signals for processing the analog-to-digital signal conversion of the latch comparator device according to an embodiment of the invention.

FIG. 4 illustrates a flow chart of an operational process according to an embodiment of the invention.

FIG. 5 illustrates a flow chart of a pre-amplification process according to an embodiment of the invention.

FIG. 6 illustrates a flow chart of a voltage shift process according to an embodiment of the invention.

FIG. 7 illustrates a flow chart of a latch operational process according to an embodiment of the invention.

### DETAILED DESCRIPTION

In the specification and the claim of the present invention may use a particular word to indicate an element, which may have diversified names named by distinct manufacturers. The present invention distinguishes the element depending on its function rather than its name. The phrase “comprising” used in the specification and the claim is to mean “is inclusive or open-ended but not exclude additional, un-recited elements or method steps.” In addition, the phrase “electrically connected to” or “coupled” is to mean any electrical connection in a direct manner or an indirect manner. Therefore, the description of “a first device electrically connected or coupled to a second device” is to mean that the first device is connected to the second device directly or by means of connecting through other devices or methods in an indirect manner.

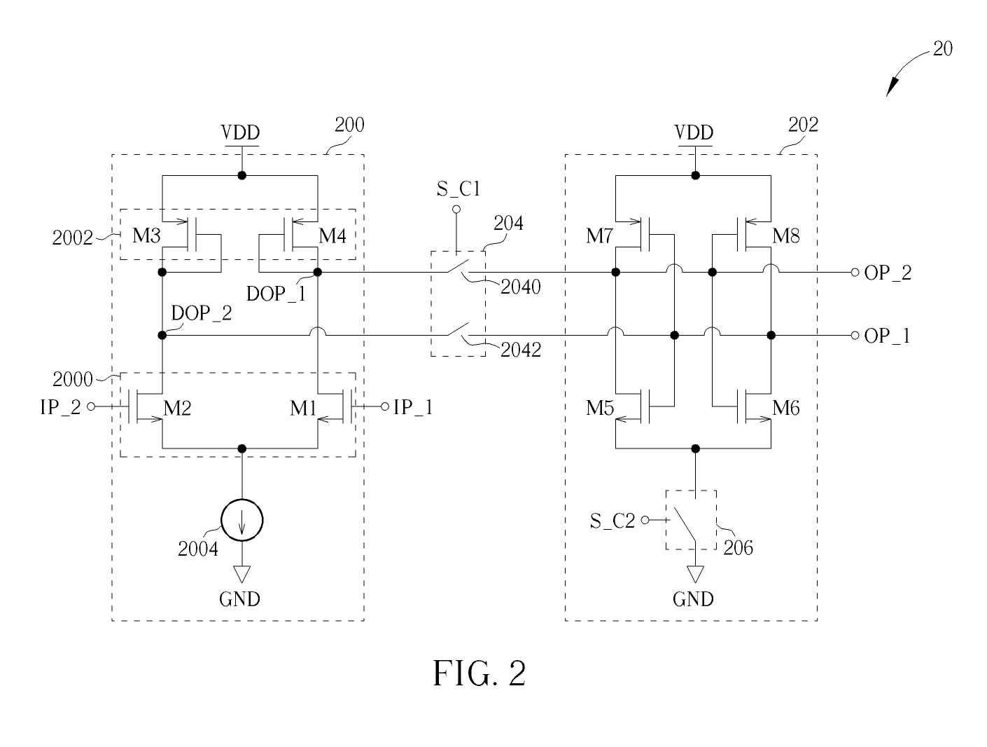

Please refer to FIG. 2, which illustrates a schematic diagram of a latch comparator device 20 according to an embodiment of the invention. As shown in FIG. 2, the latch comparator device 20 comprises a differential input amplifier 200, a latch 202, a switch module 204 and a third switch device 206. The differential input amplifier 200 is coupled between a first system voltage (such as a stable voltage source VDD) and a second system voltage (such as a grounding voltage GND or other referenced voltage sources), wherein the differential input amplifier comprises a first differential output signal terminal DOP_1 and a second differential output signal terminal DOP_2. The latch 202 is coupled to a third system voltage (such as the same stable voltage source VDD as the first system voltage) and comprises a first latch signal terminal OP_1 and a second latch signal terminal OP_2. The switch module 204 comprises a first switch device 2040 and a second switch device 2042. The first switch device 2040 is coupled between the first differential output signal terminal DOP_1 and the second latch signal terminal OP_2, and the second switch device 2042 is coupled between the second differential output signal terminal DOP_2 and the first latch signal terminal OP_1. Besides, the third switch device 206 is coupled between the latch 202 and a fourth system voltage (such as the same grounding voltage GND as the second system voltage).

In FIG. 2, a detailed schematic diagram of the differential input amplifier 200 is also shown according to an embodiment of the invention. In the embodiment, the differential input amplifier 200 comprises a differential input module 2000, a load module 2002 and a current source 2004. The differential input module 2000 can be realized via a first input transistor M1 and a second input transistor M2, and is not limited herein. The load module 2002 can be realized via a first load transistor M3 and a second load transistor M4, and is not limited herein. The current source 2004 is only utilized for providing the stable current, and does not limit the scope of the invention.

In the embodiment, the first input transistor M1 and the second input transistor M2 are realized as the first type MOS transistor (such as the PMOS), and the first load transistor M3 and the second load transistor M4 are realized as the second type MOS transistor (such as the PMOS). Gates of the first input transistor M1 and the second input transistor M2 are utilized as a first differential input signal terminal IP_1 and a second differential input signal terminal IP_2, respectively. Sources of the first input transistor M1 and the second input transistor M2 are coupled to one terminal of the current source 2004, and drains of the first input transistor M1 and the second input transistor M2 are coupled to drains of the second load transistor M4 and the first load transistor M3, respectively. The drain of the first load transistor M3 is coupled to a gate of the first load transistor M3 to form the second differential output signal terminal DOP_2. The drain of the second load transistor M4 is coupled to a gate of the second load transistor M4 to form the first differential output signal terminal DOP_1. Sources of the second load transistor M4 and the first load transistor M3 are coupled to the first system voltage VDD, and another terminal of the current source 2004 is coupled to the second system voltage GND.

Noticeably, the transistors M3, M4 of the load module 2002 can be formed as a diode-connected load, and more specifically, can be formed as an NMOS diode-connected load. In other embodiments, the transistors M3, M4 can also be replaced as diodes or other numbers/types of diode-connected loads, which is also in the scope of the invention. Certainly, the other embodiments can utilize different types of the load modules due to practical requirements, such as a resistive load, a combination load, an active type load or a passive type load, which is not described herein for brevity.

Please refer to FIG. 2 again. The switch module 204 is coupled between the differential input amplifier 200 and the latch 202, and comprises a first switch device 2040 and a second switch device 2042 to be coupled to the first differential output signal terminal DOP_1 and the second differential output signal terminal DOP_2, respectively. The first switch device 2040 and the second switch device 2042 are correspondingly conducted via a first control signal S_C1. Accordingly, based on conduction conditions of the first switch device 2040 and the second switch device 2042, the first differential output signal terminal DOP_1 and the second differential output signal terminal DOP_2 are connected or broken with the second latch signal terminal OP_2 and the first latch signal terminal OP_1, respectively.

Further, a detailed schematic diagram of the latch 202 is also shown according to an embodiment of the invention. In the embodiment, the latch 202 comprises a first latch transistor M5, a second latch transistor M6, a third latch transistor M7 and a fourth latch transistor M8, wherein the first latch transistor M5 and the second latch transistor M6 can be realized as the first type MOS transistor (such as the PMOS) and the third latch transistor M7 and the fourth latch transistor M8 can be realized as the second type MOS transistor (such as the NMOS).

In detail, within the latch 202, gates of the first latch transistor M5 and the third latch transistor M7 are coupled to each other, and are coupled to the second switch device 2042, drains of the second latch transistor M6 and the fourth latch transistor M8, to form the first latch signal terminal OP_1. Similarly, drains of the first latch transistor M5 and the third latch transistor M7 are coupled to each other, and are coupled to the first switch device 2040, gates of the second latch transistor M6 and the fourth latch transistor M8, to form the second latch signal terminal OP_2.

According to different perspectives, the first latch transistor M5 and the third latch transistor M7 can be regarded as a first complementary transistor pair, such that a source of the first latch transistor M5 is coupled to the third switch device 206 and a source of the third latch transistor M7 is coupled to the third system voltage VDD. Symmetrically, the second latch transistor M6 and the fourth latch transistor M8 can be regarded as a second complementary transistor pair, such that a source of the second latch transistor M6 is coupled to the third switch device 206 and a source of the fourth latch transistor M8 is coupled to the third system voltage VDD. Besides, the first complementary transistor pair and the second complementary transistor pair are coupled to each other via the first latch signal terminal OP_1 and the second latch signal terminal OP_2. Noticeably, other structural latches can also be utilized to cooperate with the differential input amplifier 200, and do not limit the scope of the invention.

The third switch device 206 is coupled between the latch 202 and the ground GND, and is correspondingly conducted via a second control signal S_C2. Preferably, the differential input amplifier 200 and the latch 202 are adaptively connected/disconnected to each other via the first control signal S_C1 (or regarded as a pre-amplification control signal), and the latch 202 is adaptively connected/disconnected to the ground GND via the second control signal S_C2 (or regarded as a latch control signal).

Referring to operations of the latch comparator device 20, the latch comparator device 20 receives the first differential input signal and the second differential input signal via the first differential input signal terminal IP_1 and the second differential input signal terminal IP_2, respectively, and accordingly, the pre-amplification control signal (i.e. the first control signal S_C1) and the latch control signal (i.e. the second control signal S_C2) are utilized to sequentially process a pre-amplification operation, a voltage shift operation and a latch operation, so as to process the analog-to-digital signal conversion for transforming the input differential signals.

Additionally, the latch comparator device 20 of the embodiment utilizes the switch module 204 and the third switch device 206 to be connected/disconnected at different operational periods, so as to effectively isolate electrical connection between the first differential output signal terminal DOP_1, the second differential output signal terminal DOP_2 as well as the first latch signal terminal OP_1, the second latch signal terminal OP_2. Thus, the generation of the kick back noise effect can be easily prevented to correspondingly improve the signal conversion accuracy as well as the switch mechanism, so as to increase the processing efficiency of the latch comparator device 20.

Noticeably, the embodiment of the invention has the basis of the first system voltage being equivalent to the third system voltage and the second system voltage being equivalent to the fourth system voltage, and does not limit the scope of the invention. In other embodiments, those skilled in the art can adaptively exchange the utilization of the PMOS and the NMOS for practical requirements.

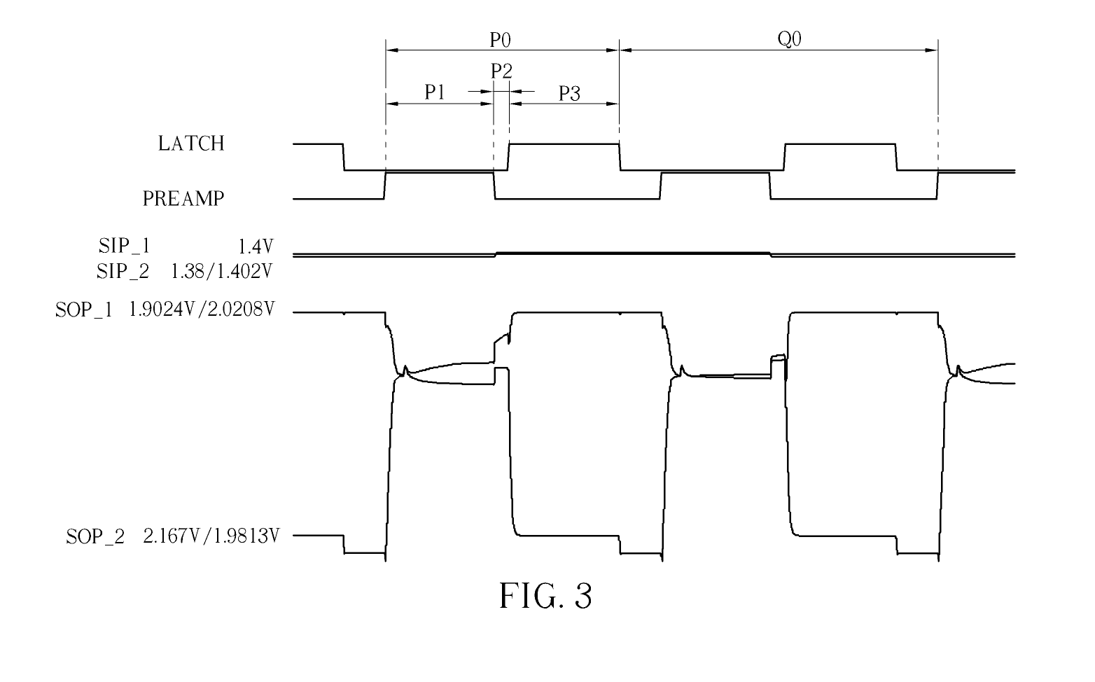

Please refer to FIG. 3, which illustrates a schematic diagram of related signals for processing the analog-to-digital signal conversion of the latch comparator device 20 according to an embodiment of the invention, wherein the first differential input signal terminal IP_1 receives the first differential input signal SIP_1, which can be a constant value as 1.4000 volts in the embodiment, and the second differential input signal terminal IP_2 receives the second differential input signal SIP_2, which can be designed as a periodical change, such as a fluctuation from 1.380 volts to 1.402 volts in the embodiment, none of which should limit the scope of the invention. As shown in FIG. 3, a first operational period P1, a second operational period P2 and a third operational period P3 correspond to changes of the related signals for processing the analog-to-digital signal conversion of the latch comparator device 20.

First, within the first operational period P1, the first differential input signal SIP_1 is 1.4000 volts, the second differential input signal terminal IP_2 is 1.380 volts, the pre-amplification control signal PREAMP is a high level signal and the latch control signal LATCH is a low level signal, such that the first switch device 2040 and the second switch device 2042 of the switch module 204 are conducted and the third switch is disconnected. Under such circumstances, the first differential output signal terminal DOP_1 and the second differential output signal terminal DOP_2 of the differential input amplifier 200 are coupled to the first latch signal terminal OP_1 and the second latch signal terminal OP_2 of the latch 202, and the first latch transistor M5 and the second latch transistor M6 of the latch 202 are disconnected from the fourth system voltage (the ground GND). Accordingly, the latch 202 is utilized as a load of the differential input amplifier 200, and the latch 202 samples voltage levels of the first differential output signal and the second differential output signal, such that a first initial voltage level of the first latch output signal SOP_1 and a second initial voltage level of the second latch output signal SOP_2 are generated at the first latch signal terminal OP_1 and the second latch signal terminal OP_2. In other words, the first initial voltage level and the second initial voltage level are stored at the first latch signal terminal OP_1 and the second latch signal terminal OP_2 of the latch 202, respectively.

For example, the first input transistor M1 has a gain gₘ₁, the first load transistor M3 has a gain gₘ₃, the third latch transistor M7 has a gain gₘ₇, and the gain gₘ₇ of the third latch transistor is smaller than the gain gₘ₃ of the first load transistor M3. Besides, the first differential input signal terminal IP_1 and the second differential input signal terminal IP_2 are formed to be an input signal voltage difference VIN, and the first latch signal terminal OP_1 and the second latch signal terminal OP_2 are formed to be an output signal voltage difference VOUT, such that the output signal voltage difference VOUT and the input signal voltage difference VIN, within the first operational period P1, form a ratio of

$$\frac{VOUT}{VIN} = \frac{{g}_{m 1}}{{g}_{m 3} - {g}_{m 7}} .$$

Next, within the second operational period P2, the pre-amplification control signal PREAMP and the latch control signal LATCH are the low level signals, such that the first switch device 2040, the second switch device 2042 of the switch module 204 and the third switch 206 are disconnected, which means that the first differential output signal terminal DOP_1 and the second differential output signal terminal DOP_2 are disconnected from the first latch signal terminal OP_1 and the second latch signal terminal OP_2, and the first latch transistor M5 and the second latch transistor M6 are disconnected from the fourth system voltage (i.e. the ground GND) as well. Under such circumstances, the latch comparator 20 processes the voltage shift operation, and the voltage levels of the first latch output signal SOP_1 and the second latch output signal SOP_2 shift from the first initial voltage level and the second initial voltage level toward the same direction, for example, both increasing by 0.0005 volts. In the embodiment, the voltage level of the first latch output signal SOP_1 is 2.167 volts, and the voltage level of the second latch output signal SOP_2 is 1.9024 volts.

Last, within the third operational period P3, the pre-amplification control signal PREAMP is the low level signal and the latch control signal LATCH is the high level signal, such that the first switch module 2040 and the second switch device 2042 of the switch module 204 are disconnected and the third switch 206 is conducted, which means the first differential output signal terminal DOP_1 and the second differential output signal terminal DOP_2 are disconnected from the first latch signal terminal OP_1 and the second latch signal terminal OP_2, and the first latch transistor M5 and the second latch transistor M6 are connected with the ground GND. Under such circumstances, the latch comparator device 20 processes the latch operation, and the latch 202 regenerates voltage levels of the first latch output signal SOP_1 and the second latch output signal SOP_2 according to the first initial voltage level and the second initial voltage level, and the voltage levels of the first latch output signal SOP_1 and the second latch output signal SOP_2 comply with voltage levels of the digital signal. This means the voltage level of the second latch output signal SOP 2 equals to the digital signal of VDD, and the voltage level of the first latch output signal SOP_1 equals to the digital signal of GND.

Noticeably, another reversal operation can be operated after the latch comparator device 20 finishes related operations corresponding to the first operational period P1, the second operational period P2 and the third operational period P3. Accordingly, the first differential input signal SIP_1 is fixed at 1.4000 volts, and the second differential input signal terminal IP_2 is changed to be 1.402 volts. The pre-amplification control signal PREAMP and the latch control signal LATCH are the low level signals, and after a period, the pre-amplification control signal PREAMP becomes the high level signal and the latch control signal LATCH maintains the low level signal. Under such circumstances, the voltage levels of the first latch output signal SOP_1 and the second latch output signal SOP_2 outputted from the first latch signal terminal OP_1 and the second latch signal terminal OP_2, respectively, are ready for reversing, which means a newly generated voltage level of the second latch output signal SOP_2 is similar to the original variation of the first latch output signal SOP_1, and a newly generated voltage level of the first latch output signal SOP_1 is similar to the original variation of the second latch output signal SOP_2. Detailed operations can be referenced based on the related operations corresponding to the first operational period P1, the second operational period P2 and the third operational period P3, and are not described herein. In other words, the latch comparator device 20 can be divided into a normal operational period P0 and a reversal operational period Q0, and the mentioned operational periods are symmetrical for the pre-amplification operation, the voltage shift operation and the latch operation, so as to process the analog-to-digital signal conversion for transforming the input differential signals into the outputted digital signals.

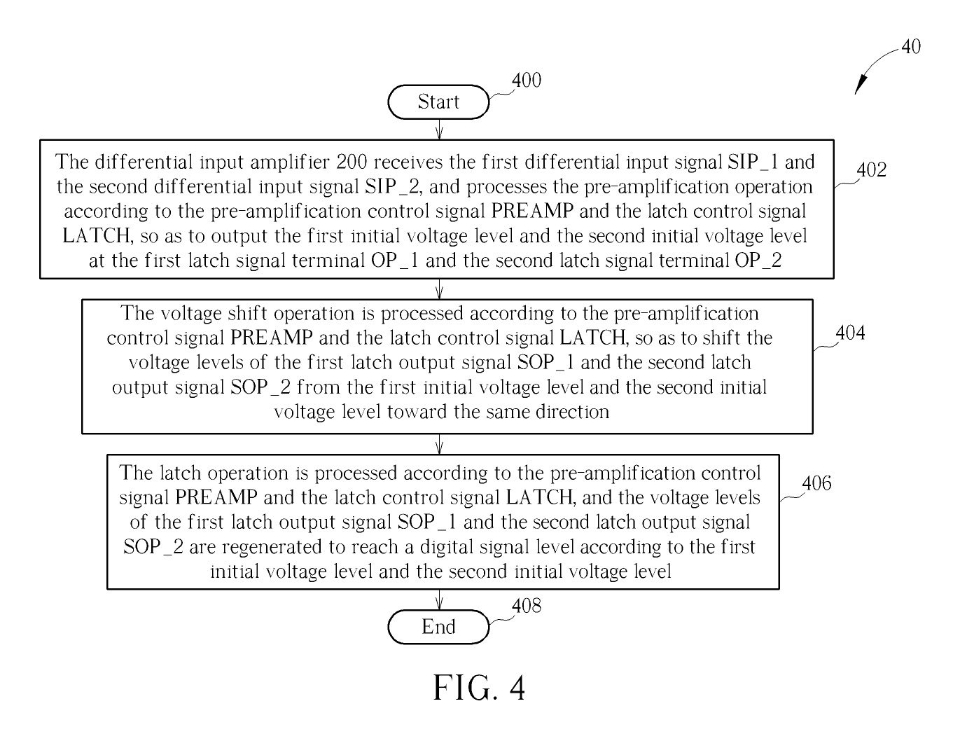

In the embodiment, an operational method applying to the latch comparator device 20 can be derived into an operational process 40, as shown in FIG. 4. The operational process 40 includes the steps as follows:

Step 400: Start.

Step 402: The differential input amplifier 200 receives the first differential input signal SIP_1 and the second differential input signal SIP_2, and processes the pre-amplification operation according to the pre-amplification control signal PREAMP and the latch control signal LATCH, so as to output the first initial voltage level and the second initial voltage level at the first latch signal terminal OP_1 and the second latch signal terminal OP_2.

Step 404: The voltage shift operation is processed according to the pre-amplification control signal PREAMP and the latch control signal LATCH, so as to shift the voltage levels of the first latch output signal SOP_1 and the second latch output signal SOP_2 from the first initial voltage level and the second initial voltage level toward the same direction.

Step 406: The latch operation is processed according to the pre-amplification control signal PREAMP and the latch control signal LATCH, and the voltage levels of the first latch output signal SOP_1 and the second latch output signal SOP_2 are regenerated to reach a digital signal level according to the first initial voltage level and the second initial voltage level.

Step 408: End.

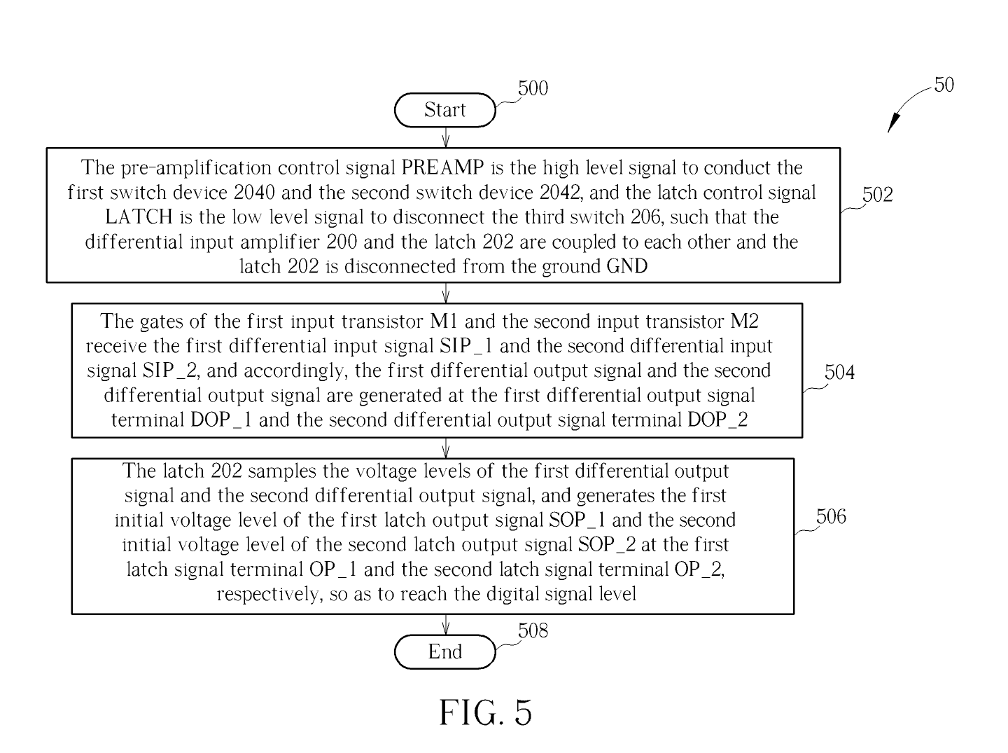

Additionally, detailed operations of Step 402 can be further derived into a pre-amplification operational process 50, as shown in FIG. 5. The pre-amplification operational process 50 includes the steps as follows:

Step 500: Start.

Step 502: The pre-amplification control signal PREAMP is the high level signal to conduct the first switch device 2040 and the second switch device 2042, and the latch control signal LATCH is the low level signal to disconnect the third switch 206, such that the differential input amplifier 200 and the latch 202 are coupled to each other and the latch 202 is disconnected from the ground GND.

Step 504: The gates of the first input transistor M1 and the second input transistor M2 receive the first differential input signal SIP_1 and the second differential input signal SIP_2, and accordingly, the first differential output signal and the second differential output signal are generated at the first differential output signal terminal DOP_1 and the second differential output signal terminal DOP_2.

Step 506: The latch 202 samples the voltage levels of the first differential output signal and the second differential output signal, and generates the first initial voltage level of the first latch output signal SOP_1 and the second initial voltage level of the second latch output signal SOP_2 at the first latch signal terminal OP_1 and the second latch signal terminal OP_2, respectively, so as to reach the digital signal level.

Step 508: End.

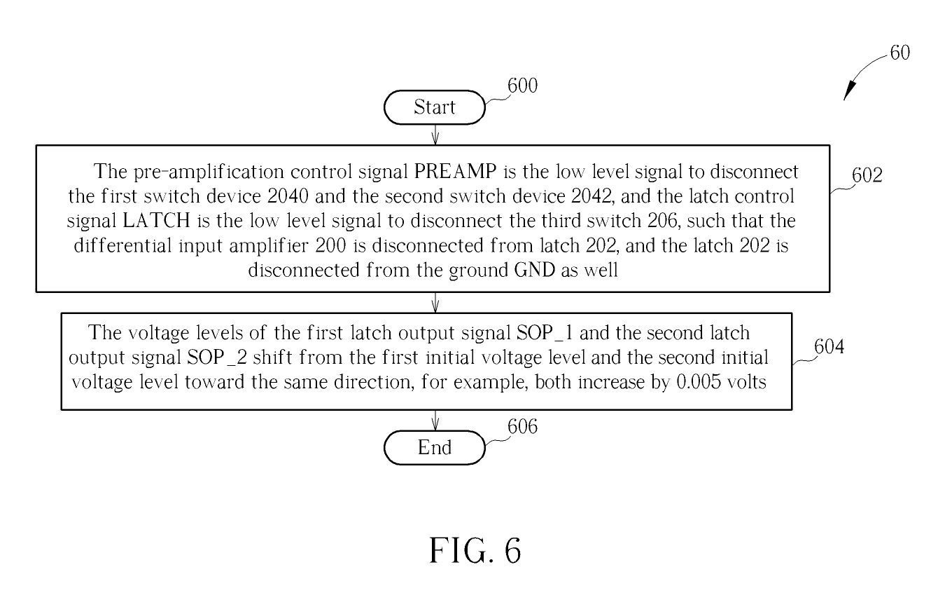

Additionally, detailed operations of Step 404 can be further derived into a voltage shift process 60, as shown in FIG. 6. The voltage shift process 60 includes the steps as follows:

Step 600: Start.

Step 602: The pre-amplification control signal PREAMP is the low level signal to disconnect the first switch device 2040 and the second switch device 2042, and the latch control signal LATCH is the low level signal to disconnect the third switch 206, such that the differential input amplifier 200 is disconnected from latch 202, and the latch 202 is disconnected from the ground GND as well.

Step 604: The voltage levels of the first latch output signal SOP_1 and the second latch output signal SOP_2 shift from the first initial voltage level and the second initial voltage level toward the same direction, for example, both increase by 0.005 volts.

Step 606: End

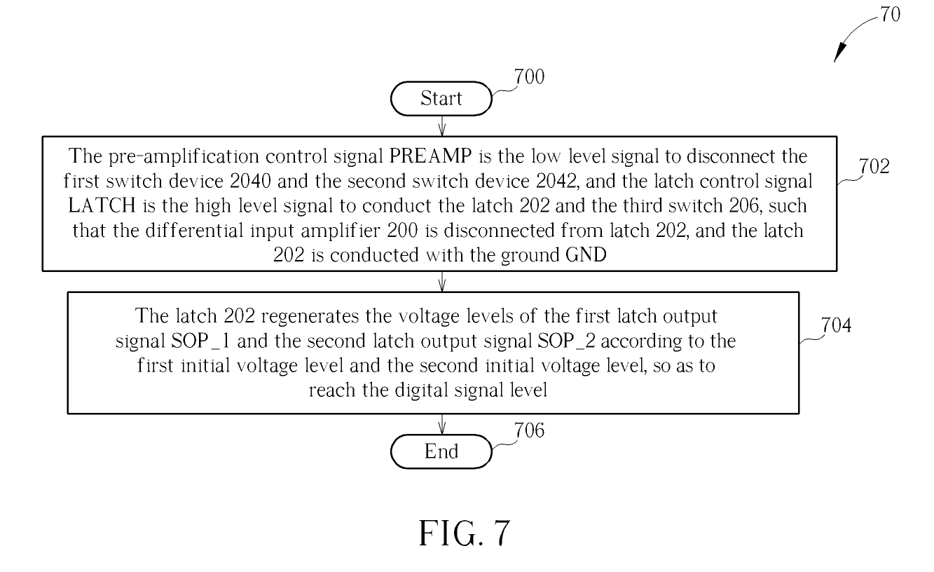

Additionally, detailed operations of Step 406 can be further derived into a latch operational process 70, as shown in FIG. 7. The latch operational process 70 includes the steps as follows:

Step 700: Start.

Step 702: The pre-amplification control signal PREAMP is the low level signal to disconnect the first switch device 2040 and the second switch device 2042, and the latch control signal LATCH is the high level signal to conduct the latch 202 and the third switch 206, such that the differential input amplifier 200 is disconnected from latch 202, and the latch 202 is conducted with the ground GND.

Step 704: The latch 202 regenerates the voltage levels of the first latch output signal SOP_1 and the second latch output signal SOP_2 according to the first initial voltage level and the second initial voltage level, so as to reach the digital signal level.

Step 706: End

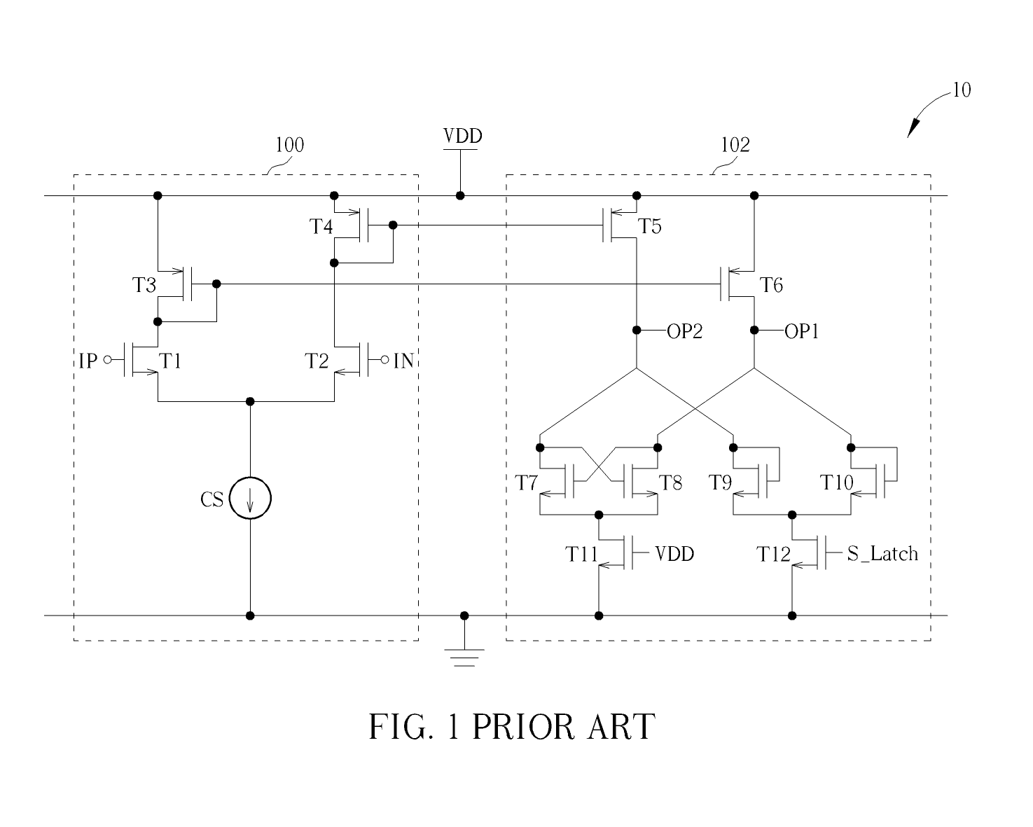

Detailed operations of the operational process 40, the pre-amplification operational process 50, the voltage shift process 60 and the latch operational process 70 can be understood via the above embodiments, FIG. 1 to FIG. 3 and the related paragraphs thereof, which are not described herein. In the embodiment, a voltage level difference of the first differential input signal SIP_1 and the second differential input signal SIP_2 is only 0.02 volts which is a small signal (i.e. a difference between 1.4 volts and 1.38 volts). After processing the pre-amplification operational process 50, the voltage shift process 60 and the latch operational process 70, a larger signal of 0.26 volts is correspondingly obtained across the first latch signal terminal OP_1 and the second latch signal terminal OP_2 (i.e. a difference between 1.9024 volts and 2.167 volts). Besides, those skilled in the art can simultaneously consider responsive periods, layout areas and gate numbers of the transistors utilized in the embodiment, to adaptively adjust channel conditions of the transistors utilized in the embodiment, so as to obtain a gain ranging from 10 to 20, which does not limit the scope of the invention. Noticeably, the embodiment utilizes the same control signal to simultaneously conduct/disconnect the first switch device 2040 and the second switch device 2042, which does not limit the scope of the invention. Thus, those skilled in the art can adaptively modify conductive periods and/or disconnecting periods of the embodiments, such as separating the conductive periods and/or disconnecting periods by a predetermined period.

In summary, the embodiments of the invention provide a latch comparator device and an operational method thereof, which utilize a plurality of switch devices coupled between a differential input amplifier, a latch and a ground. Based on a pre-amplification control signal and a latch control signal for adaptively connecting/disconnecting the plurality of switch devices at different operational periods, the differential input amplifier and the latch can process a pre-amplification operation, a voltage shift operation and a latch operation at different operational periods, to correspondingly process an analog-to-digital signal conversion for transforming differential input signals (i.e. small value signals) into digital signals (i.e. large value signals). Therefore, the embodiments of the invention can avoid the generation of the kick back noise effect and correspondingly improve signal conversion accuracy as well as processing efficiency thereof, so as to increase application ranges of the latch comparator device.

Those skilled in the art will readily observe that numerous modifications and alterations of the device and method may be made while retaining the teachings of the invention. Accordingly, the above disclosure should be construed as limited only by the metes and bounds of the appended claims.

1. A latch comparator device for processing an analog-to-digital signal transformation comprising:
a differential input amplifier coupled between a first system voltage and a second system voltage and comprising a first differential output signal terminal and a second differential output signal terminal;
a latch connected to a third system voltage, and comprising a first latch signal terminal and a second latch signal terminal;
a switch module comprising a first switch device and a second switch device, wherein the first switch device is coupled between the first differential output signal terminal and the second latch signal terminal and the second switch device is coupled between the second differential output signal terminal and the first latch signal terminal; and
a third switch device coupled between the latch and a fourth system voltage.

2. The latch comparator device of claim 1, wherein the first switch device and the second switch device receive a first control signal to be turned on/off, and the third switch device receives a second control signal to be turned on/off.

3. The latch comparator device of claim 1, wherein the first system voltage equals the third system voltage and the second system voltage equals the fourth system voltage.

4. The latch comparator device of claim 2, wherein
during a first operational period, the latch receives a current flowing through the third system voltage, and the first control signal is utilized to turn on the first switch device and the second switch device, and the second control signal is utilized to turn off the third switch device; and
during a second operational period after the first operational period, the first control signal is utilized to turn off the first switch device and the second switch device, and the second control signal is utilized to turn on the third switch device.

5. The latch comparator device of claim 4, wherein
during the first operational period, the latch comparator device processes a pre-amplification operation, wherein the differential input amplifier receives and amplifies a first differential input signal and a second differential input signal and generates a first differential output signal and a second differential output signal at the first differential output signal terminal and the second differential output signal terminal, respectively, and the latch is utilized as a load of the differential input amplifier to sample voltage levels of the first differential output signal and the second differential output signal and generates a first initial voltage level of the first latch output signal and a second initial voltage level of the second latch output signal at the first latch signal terminal and the second latch signal terminal, respectively; and
during the second operational period, the latch comparator device processes a latch operation, wherein the latch regenerates voltage levels of the first latch output signal and the second latch output signal according to the first initial voltage level and the second initial voltage level to reach a digital signal voltage level.

6. The latch comparator device of claim 4, wherein during a third operational period between the first operational period and the second operational period, the first control signal is utilized to turn off the first switch device and the second switch device, and the second control signal is utilized to turn off the third switch device.

7. The latch comparator device of claim 6, wherein
during the first operational period, the latch comparator device processes a pre-amplification operation, wherein the differential input amplifier receives and amplifies a first differential input signal and a second differential input signal and generates a first differential output signal and a second differential output signal at the first differential output signal terminal and the second differential output signal terminal, respectively, and the latch is utilized as a load of the differential input amplifier to sample voltage levels of the first differential output signal and the second differential output signal and generates a first initial voltage level of the first latch output signal and a second initial voltage level of the second latch output signal at the first latch signal terminal and the second latch signal terminal, respectively;
during the third operational period, the latch comparator device processes a voltage shift operation, wherein the voltage levels of the first latch output signal and the second latch output signal shift from the first initial voltage level and the second initial voltage level toward the same direction; and
during the second operational period, the latch comparator device processes a latch operation, wherein the latch regenerates voltage levels of the first latch output signal and the second latch output signal according to the first initial voltage level and the second initial voltage level to reach a digital signal voltage level.

8. The latch comparator device of claim 1, wherein the differential input amplifier comprises:
a differential input module, coupled to the first differential output signal terminal and the second differential output signal terminal;
a load module, coupled between the first differential output signal terminal, the second differential output signal terminal and the first system voltage; and
a current source, coupled between the differential input module and the second system voltage.

9. The latch comparator device of claim 8, wherein the differential input module comprises:
a first input transistor comprising a first terminal for receiving a first input signal, a second terminal coupled to the first differential output signal terminal and a third terminal coupled to the current source; and
a second input transistor comprising a first terminal for receiving a second input signal, a second terminal coupled to the second differential output signal terminal and a third terminal coupled to the current source.

10. The latch comparator device of claim 8, wherein the load module comprises:
a first load transistor comprising a first terminal, a second terminal and a third terminal, wherein the first terminal is coupled to the second terminal, the second terminal is coupled to the first differential output signal terminal and the third terminal is coupled to the first system voltage; and
a second load transistor comprising a first terminal, a second terminal and a third terminal, wherein the first terminal is coupled to the second terminal, the second terminal is coupled to the second differential output signal terminal and the third terminal is coupled to the first system voltage.

11. The latch comparator device of claim 8, wherein the load module comprises a plurality of diode-connected loads, wherein each of the plurality of diode-connected loads is coupled to the first differential output signal terminal or the second differential output signal terminal, and is further coupled to the first system voltage.

12. The latch comparator device of claim 11, wherein each of the plurality of diode-connected loads comprises a load transistor comprising a first terminal, a second terminal and a third terminal, wherein the first terminal is coupled to the second terminal, the second terminal is coupled to the first differential output signal terminal or the second differential output signal terminal, and the third terminal is coupled to the first system voltage.

13. The latch comparator device of claim 1, wherein the latch comprises:
a first latch transistor comprising a first terminal, a second terminal and a third terminal, wherein the first terminal is coupled to the second latch signal terminal, the second terminal is coupled to the first latch signal terminal and the third terminal is coupled to the third switch device;
a second latch transistor comprising a first terminal, a second terminal and a third terminal, wherein the first terminal is coupled to the first latch signal terminal, the second terminal is coupled to the second latch signal terminal and the third terminal is coupled to the third switch device;
a third latch transistor comprising a first terminal, a second terminal and a third terminal, wherein the first terminal is coupled to the second latch signal terminal, the second terminal is coupled to the first latch signal terminal and the third terminal is coupled to the third system voltage; and
a fourth latch transistor comprising a first terminal, a second terminal and a third terminal, wherein the first terminal is coupled to the first latch signal terminal, the second terminal is coupled to the second latch signal terminal and the third terminal is coupled to the third system voltage.

14. The latch comparator device of claim 1, wherein the latch comprises:
a first complementary transistor pair coupled between the third system voltage and the third switch device; and
a second complementary transistor pair coupled between the third system voltage and the third switch device;
wherein the first complementary transistor pair and the second complementary transistor pair are serially connected at the first latch signal terminal and the second latch signal terminal.

15. A latch comparator device for processing an analog-to-digital signal transformation comprising:
a differential input amplifier comprising:
a differential input module, coupled to a first differential output signal terminal and a second differential output signal terminal;
a load module, coupled between the first differential output signal terminal, the second differential output signal terminal and a first system voltage; and
a current source, coupled between the differential input module and a second system voltage; and
a latch comprising:
a first latch transistor comprising a first terminal, a second terminal and a third terminal, wherein the second terminal is coupled to a first latch signal terminal, the first terminal is coupled to a second latch signal terminal and the third terminal is coupled to a third switch device;
a second latch transistor comprising a first terminal, a second terminal and a third terminal, wherein the first terminal is coupled to the first latch signal terminal, the second terminal is coupled to the second latch signal terminal and the third terminal is coupled to the third switch device;
a third latch transistor comprising a first terminal, a second terminal and a third terminal, wherein the first terminal is coupled to the second latch signal terminal, the second terminal is coupled to the first latch signal terminal and the third terminal is connected to the first system voltage; and
a fourth latch transistor comprising a first terminal, a second terminal and a third terminal, wherein the first terminal is coupled to the first latch signal terminal, the second terminal is coupled to the second latch signal terminal and the third terminal is connected to the first system voltage; and
a switch module comprising a first switch device and a second switch device, wherein the first switch device is coupled between the first differential output signal terminal and the second latch signal terminal and the second switch device is coupled between the second differential output signal terminal and the first latch signal terminal; and
a third switch device, coupled between the latch and the second system voltage.

16. The latch comparator device of claim 15, wherein
during a first operational period, a first control signal is utilized to turn on the first switch device and the second switch device, and a second control signal is utilized to turn off the third switch device; and
during a second operational period after the first operational period, the first control signal is utilized to turn off the first switch device and the second switch device, and the second control signal is utilized to turn on the third switch device.

17. The latch comparator device of claim 16, wherein during a third operational period between the first operational period and the second operational period, the first control signal is utilized to turn off the first switch device and the second switch device, and the second control signal is utilized to turn off the third switch device.

18. The latch comparator device of claim 14, wherein the differential input module comprises:
a first input transistor comprising a first terminal for receiving a first input signal, a second terminal coupled to the first differential output signal terminal and a third terminal coupled to the current source; and
a second input transistor comprising a first terminal for receiving a second input signal, a second terminal coupled to the second differential output signal terminal and a third terminal coupled to the current source.

19. The latch comparator device of claim 15, wherein the load module comprises:
a first load transistor comprising a first terminal, a second terminal and a third terminal, wherein the first terminal is coupled to the second terminal, the second terminal is coupled to the first differential output signal terminal and the third terminal is coupled to the first system voltage; and
a second load transistor comprising a first terminal, a second terminal and a third terminal, wherein the first terminal is coupled to the second terminal, the second terminal is coupled to the second differential output signal terminal and the third terminal is coupled to the first system voltage.

20. An operational method for a latch comparator device comprising a differential input amplifier and a latch, the operational method comprising:
processing a pre-amplification operation, wherein the pre-amplification operation comprises:
disconnecting the latch from a first system voltage while connecting the latch with a second system voltage such that the latch receives a current flowing through the second system voltage;
connecting the differential input amplifier and the latch;
utilizing the differential input amplifier to receive and amplify a first differential input signal and a second differential input signal, so as to generate a first differential output signal and a second differential output signal; and
utilizing the latch to sample voltage levels of the first differential output signal and the second differential output signal, so as to generate a first initial voltage level of a first latch output signal and a second initial voltage level of a second latch output signal; and
processing a latch operation after the pre-amplification operation, wherein the latch operation comprises:
disconnecting the differential input amplifier and the latch;
connecting a side of the latch to the system voltage; and
utilizing the latch to regenerate voltage levels of the first latch output signal and the second latch output signal according to the first initial voltage level and the second initial voltage level, to reach a digital signal voltage level.

21. The operational method of claim 20, further comprising processing a voltage shift operation between the pre-amplification operation and the latch operation, wherein the voltage shift operation further comprises:
maintaining a disconnection between the latch and the system voltage and disconnecting the differential input amplifier and the latch, to make voltage levels of the first latch output signal and the second latch output signal shift from the first initial voltage level and the second initial voltage level toward the same direction.
